(19) United States
(12) Patent Application Publication
(10) Pub. No.: US 2018/0195205 A1
(43) Pub. Date: Jul. 12, 2018

(54) Hierarchically Controlled Inside-Out Doping of Mg Nanocomposites for Moderate Temperature Hydrogen Storage

(71) Applicants: The Regents of the University of California, Oakland, CA (US); Lawrence Livermore National Security, LLC, Livermore, CA (US); Sandia National Laboratory, Livermore, CA (US)

(72) Inventors: Jeffrey J. Urban, Emeryville, CA (US); Anne M. Ruminski, Belmont, CA (US); Eun Seon Cho, Emeryville, CA (US); Rizia Bardhan, Nashville, TN (US); Alyssa Brand, El Cerrito, CA (US); Brandon C. Wood, Livermore, CA (US); Tae Wook Heo, Dublin, CA (US); Patrick T. Shea, Livermore, CA (US); Shin Young Kang, Pleasanton, CA (US); Xiaowang Zhou, Livermore, CA (US)

(21) Appl. No.: 15/870,272

(22) Filed: Jan. 12, 2018

Related U.S. Application Data
(60) Provisional application No. 62/445,610, filed on Jan. 12, 2017.

(51) Int. Cl. C30B 29/10; B82Y 40/00; C01B 6/24; C01B 32/194; B82Y 30/00; C30B 29/60

(52) U.S. Cl. CPC C30B 29/10; B82Y 40/00; C30B 29/60; C01B 32/194; B82Y 30/00; C01B 6/24

(57) ABSTRACT

A nickel-doped Mg nanocrystals encapsulated by molecular-sieving reduced graphene oxide (rGO) layers is disclosed. Dual-channel doping, which combines external (rGO strain) and internal (Ni doping) mechanisms, efficiently promotes both hydriding and dehydriding processes of Mg nanocrystals, simultaneously improving both the kinetic and thermodynamic properties of the material. The composite achieves both high hydrogen storage capacity and excellent kinetics while maintaining robustness. The realization of three complementary functional components in one material-environmentally friendly and earth-abundant Mg for storage, Ni dopants for catalysis, and rGO layers for encapsulation-breaks new ground in metal hydrides and makes solid-state materials viable candidates for hydrogen-fueled applications.

### CROSS REFERENCE TO RELATED APPLICATIONS

This application claims priority to U.S. Provisional Application Ser. No. 62/445,610 filed Jan. 12, 2017, which application is incorporated herein by reference as if fully set forth in their entirety.

### STATEMENT OF GOVERNMENTAL SUPPORT

The invention described and claimed herein was made in part utilizing funds supplied by the U.S. Department of Energy under Contract No. DE-AC02-05CH11231 between the U.S. Department of Energy and the Regents of the University of California for the management and operation of the Lawrence Berkeley National Laboratory. The government has certain rights in this invention.

### BACKGROUND OF THE INVENTION

### Field of the Invention

The present invention relates to the field of hydrogen storage.

### Related Art

Increasing concerns regarding global reliance on fossil fuels have stimulated the search for renewable energy technologies. Hydrogen is an ideal clean energy carrier to replace carbon-based fuels. Since hydrogen can be produced from water and water is the only combustion product, it offers the potential for an ideal closed energy cycle without undesirable byproducts. Moreover, hydrogen boasts an exceptionally high gravimetric energy density (120-142 MJ kg⁻¹), compared to other energy storage materials (e.g. 44.4 MJ kg⁻¹ for gasoline, 0.17-1.8 MJ kg⁻¹ for batteries). However, the transition from fossil fuels to hydrogen energy is not simple, particularly for transportation applications, which require ample storage density to minimize refueling needs. Use of solid-state hydrogen storage materials has been identified as among the most promising methods for hydrogen energy delivery. For Fuel Cell Electric Vehicle (FCEV) applications, pressurized H₂ storage (700 bar) is the predominant technology, given the lack of safe and high capacity solid-state hydrogen storage materials. Metal hydrides such as magnesium hydride (MgH₂) have the potential to fulfill these requirements due to their high hydrogen capacity, low cost, and outstanding reversibility. They also eliminate energy costs associated with liquefaction or compression which are required for compressed storage. Furthermore, unlike other solid-state storage options such as MOFs (metal-organic frameworks), hydrogen atoms are bound to metal crystalline lattice sites upon the formation of metal hydrides, enabling a high volumetric capacity and non-cryogenic operation. Among all options for metal hydride precursors, magnesium (Mg) has unique advantages in sustainability and cost, as it is an environmentally friendly and earth-abundant element.

However, there exist stubborn kinetic and thermodynamic barriers to practical use of Mg for hydrogen storage; critical obstacles include the thermodynamic stability of the hydride phase, necessitating high operating temperatures, as well as sluggish hydrogen sorption kinetics. In general, it is extremely difficult to simultaneously achieve high capacity and fast kinetics for any single material. Encouragingly, it has been widely established that additives such as transition metal dopants and carbon based materials enhance the kinetics of solid-state hydrides. However, this effect is typically counterbalanced by a loss of capacity; additives increase the dead mass in the system without contributing to active hydrogen storage. Promisingly, nanostructuring has been shown to alleviate these kinetic barriers and reduce thermodynamic stability by taking advantage of shorter hydrogen diffusion lengths and high surface area-to-volume ratios. Despite these piecemeal advances, no single hydrogen storage material has been capable of leveraging the power of nanostructuring, catalysis, and composite stability to realize suitable performance in the three key domains—capacity, kinetics, and reliability.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 illustrates hierarchically controlled inside-out doping of Mg nanocomposites.

FIG. 2 illustrates hydrogen absorption/desorption characterization of Ni-doped rGO-Mg.

FIG. 3 illustrates Thermodynamics of Ni-doped rGO-Mg in comparison with rGO-Mg.

FIG. 4 illustrates structural analysis of Mg and Ni in the composite of Ni-doped rGO-Mg.

FIG. 5 illustrates In-situ hydrogen absorption of Ni-doped rGO-Mg.

FIG. 6 illustrates kinetic analysis for hydrogen absorption and desorption of Ni-doped rGO Mg.

FIG. 7 illustrates TEM images of Ni-doped rGO-Mg.

FIG. 8 illustrates hydrogen absorption behavior of a series of 3d-transition metal doped rGO-Mg composites at 15 bar of H₂ and 200° C.; each solid and dashed line represent the absorption of the first and the second hydrogen sorption cycles, respectively.

FIG. 9 illustrates hydrogen absorption of Ti-doped rGO-Mg composite at 25° C./15 bar of H₂.

FIG. 10 illustrates hydrogen absorption of Ni-doped rGO-Mg at 15 bar of H₂ measured for 12 hours.

FIG. 11 illustrates the van't Hoff plots from Pressure-composition-temperature (PCT) results.

### DETAILED DESCRIPTION

In the discussions that follow, various process steps may or may not be described using certain types of manufacturing equipment, along with certain process parameters. It is to be appreciated that other types of equipment can be used, with different process parameters employed, and that some of the steps may be performed in other manufacturing equipment without departing from the scope of this invention. Furthermore, different process parameters or manufacturing equipment could be substituted for those described herein without departing from the scope of the invention.

These and other details and advantages of the present invention will become more fully apparent from the following description taken in conjunction with the accompanying drawings.

Here we report the synthesis of a hierarchically ordered multi-component composite with synthetic control across atomic (dopant), nano (Mg crystals), and mesoscopic (rGO encapsulating layer) length scales to address these entangled issues of kinetics and thermodynamics. The high reactivity of zero-valent Mg has restricted their preparation and use under controllable conditions. Nanosizing Mg and MgH₂ radically improves their hydrogen sorption properties; however, nanostructuring also causes the materials to become more reactive. The synthetic methods for creating nanostructured materials have been mainly focused on mechanical milling and gas-phase condensation, resulting in irregular size distributions and deteriorative particles due to agglomeration. In such synthetic routes, the addition of transition metals or carbon-based materials meant to advance the kinetic or thermodynamic properties often decimates structural control, adding undesired structural degrees of freedom. Furthermore, Mg nanocrystals are extremely vulnerable to aggregation and oxidation and are highly pyrophoric, restricting their use to inert environments. Thus, the nanostructured Mg-based system requires an appropriate passivating matrix prior to safe implementation in vehicles.

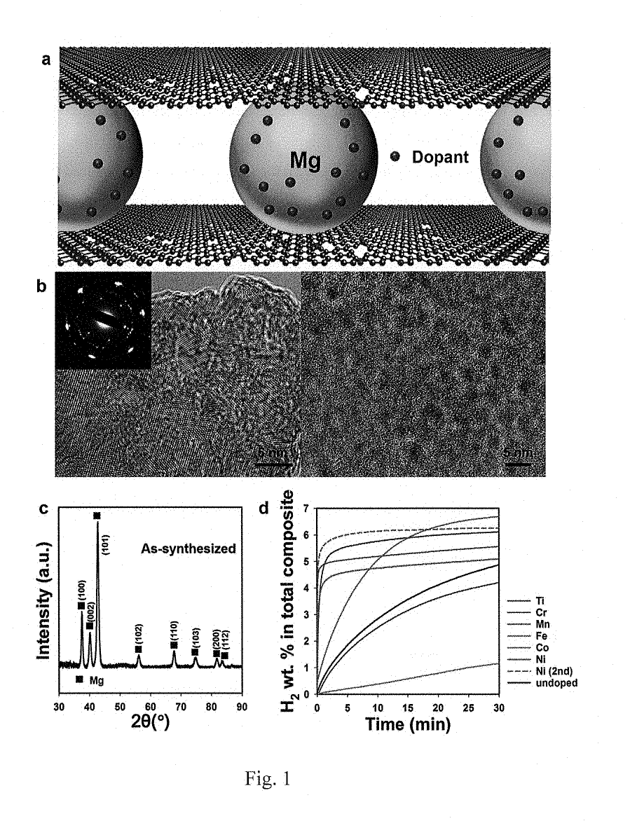

We have shown that nanostructuring of Mg improves the hydrogen absorption/desorption rates over comparable bulk Mg, approaching activation energies of some transition metal catalyzed bulk Mg crystals. Moreover, the interface between graphene layers and Mg nanocrystals further enhances kinetics, a result we attribute to local strain fields. Also, these gas-selective reduced graphene oxide (rGO) encapsulating layers were found to provide remarkable protection of Mg nanocrystals from oxidation, preserving the zero-valent Mg state in air. Further, the literature has established that either alloying Mg with transition metals or incorporation of these transition metals as a dopant considerably enhances hydrogen absorption/desorption properties, although this has been challenging to integrate with metal hydride nanocrystal synthesis in a controlled fashion. Motivated by our previous work and the doping effects of these transition metals, we aimed to encapsulate the transition metal doped Mg crystals by rGO layers to provide an atomically thin protecting layer that prevents oxidation of the encased zero-valent metals, a phenomenon which is attributed to the high hydrogen-selectivity of GO/rGO sheets. This exceptional oxidative stability removes the potential risk of explosion from nanostructured Mg systems in hydrogen storage applications, while simultaneously minimizing dead mass in the system (the rGO layers occupy only up to 2 wt. % theoretically). Moreover, the rGO layers have a beneficial effect on hydrogen sorption of encapsulated Mg crystals, and it is expected that such hydriding/dehydriding properties would be further enhanced by the addition of a transition metal dopant, producing dual-channel doping which couples externally (rGO layer) and internally (transition metal) (FIG. 1a). Leveraging these two synergistic effects, we report here the first example of controlled, nano-alloyed Mg crystals wrapped by rGO layers which exhibit both kinetic and thermodynamic enhancement for hydrogen storage.

3d-Transition Metal Doped Mg Crystals.

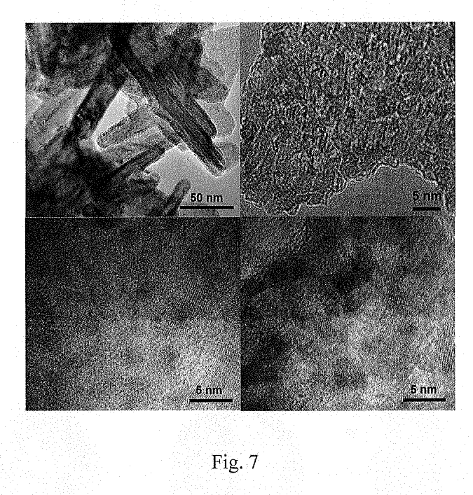

Transition metal doped Mg crystals encapsulated by rGO layers were prepared by modifying previously reported methods via a solution-based, one-pot synthesis, whereas most other studies achieved the material doping using either mechanical milling or gas condensation methods; these approaches are subject to a critical vulnerability in the aspect of lack of structural control or difficulty to implement in a large-scale synthesis of nanocrystalline matter. In this synthetic procedure, the Mg precursor, transition metal precursor, and GO are simultaneously reduced in a one-pot to form zero-valent Mg and transition metals encapsulated by rGO sheets as previously depicted. A series of canonical 3d-transition metals—Ti, Cr, Mn, Fe, Co, and Ni—were studied as candidate dopants, and doping concentrations were maintained at 5 mol. % in Mg to isolate the effect of varying the transition metal. Representative TEM images of the Ni-doped rGO-Mg nanocomposites are shown in FIG. 1b (see also FIG. 7). In contrast to undoped rGO-Mg samples previously reported, some amount of irregularly shaped Mg crystals were also observed after transition metal doping; both 3-4 nm sized nanocrystals, consistent with those found in undoped samples, and larger crystallites were observed. The Mg crystalline structure was confirmed by diffraction patterns obtained via TEM (FIG. 1b inset). XRD was used for bulk diffraction analysis (FIG. 1c); however, the crystalline peak related to the doping element was not detected. It is possible that the reduced Ni metal in the synthetic procedure exists in amorphous form or very fine particles. Interestingly, the (100) Mg peak is relatively strong compared to the (002) peak, in contrast to undoped Mg crystals where it is similar to or even slightly weaker than the (002) peak. We hypothesize that the difference arises from the accommodation of local strain fields induced by the dopant atoms, which modified the scattering factors of the unit cell.

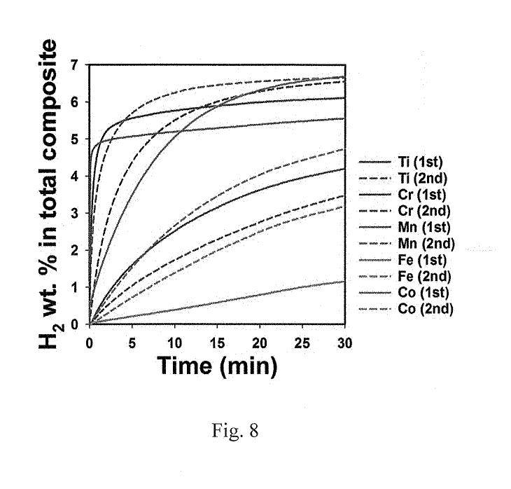

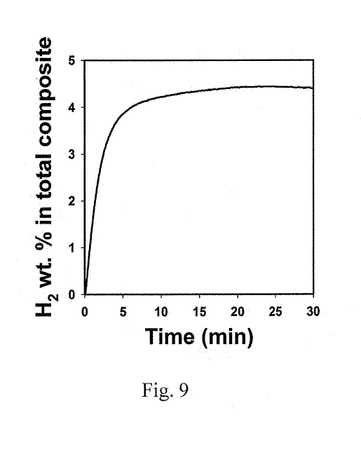

Hydrogen absorption properties of a series of the doped composites were examined (FIG. 1d). Among the transition metals tested, Ni, Cr and Mn display superior absorption rates compared to other dopants during their first absorption. The performance of these materials was probed further by desorbing the hydrogen fully under vacuum at 300° C. and carrying out a second absorption cycle (see FIG. 8). Surprisingly, at this point the kinetics of Cr and Mn doped composites deteriorate (see FIG. 8), while the Ni doped composite performs even better on this and dozens of subsequent measurements with no hysteresis. We hypothesize that the Ni dopant is catalytically activated during the first absorption procedure, and is thus more effective in both kinetics and hydrogen capacity during subsequent hydrogen desorption/absorption cycles. We note that this type of activation behavior is common for energy storage materials. The data also indicate that the catalytic effects of transition metal dopants other than Ni are not completely reversible. This includes the Ti-doped Mg crystals, which readily absorb hydrogen during initial measurements even at room temperature (see FIG. 9). In light of this result, further characterization is focused on Ni-doped rGO-Mg composites to probe the thermodynamic and kinetic contributions of the Ni dopant to the overall composite performance.

### Hydrogen Sorption Properties of Ni-Doped Mg Crystals Encapsulated by rGO Layers.

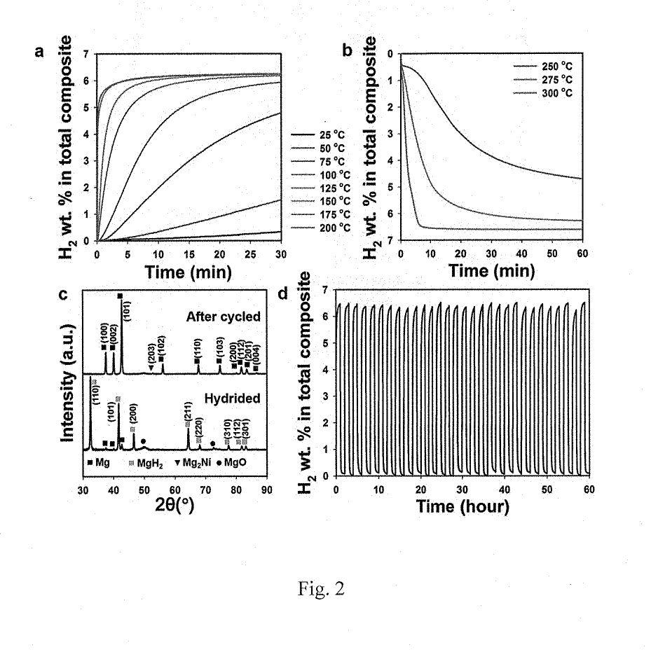

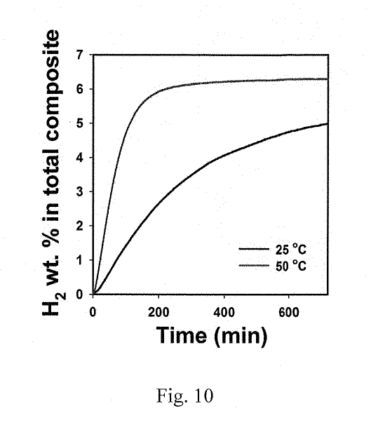

To investigate hydrogen sorption properties of these systems, hydrogen absorption/desorption tests were performed as a function of temperature at a H₂ pressure of 15 bar/0 bar, respectively (FIG. 2a). Remarkably, it absorbed 6.5 wt. % hydrogen at 200° C., of which 90% was completed within 2.5 minutes—to our knowledge, this is the best performance reported to date for any reversible solid-state storage material when considering both capacity and kinetics under a comparable condition. With the exception of the data at 25° C. (which absorbed 5.1 wt. % of hydrogen), greater than 6.3 wt. % hydrogen was absorbed at all tested temperatures (see FIG. 10). Complete desorption was achieved at 300° C.; 90% of hydrogen was desorbed within 4.6 minutes (FIG. 2b). The formation of MgH₂ upon hydriding and the complete restoration of Mg nanocrystals upon dehydriding were confirmed via XRD (FIG. 2c). Noticeably, Mg—Ni nano-alloy (including Mg₂Ni) crystallites were observed in the cycled samples. Also of note in these samples is that the intensities of the (100) and (002) Mg peaks are of similar magnitude. This is in direct contrast to as-synthesized samples (FIG. 1c). This suggests that during the room temperature synthesis Ni-containing phase was dissolved in the Mg lattice forming a solid solution, followed by alloying with Mg during an elevated temperature process. Since the evolution of this Mg—Ni nano-alloy is coincident with the transition to accelerated, stable, and reversible hydrogen sorption rates after the first absorption/desorption cycle, it is likely that Mg—Ni alloying plays a crucial role in the catalytic phenomenon. This conclusion is also consistent with the lack of similar catalytic effects with other transition metal dopants where no such alloy phases were observed.

Upon hydriding, most of the crystalline Mg phase was converted to MgH₂, based on analysis of the relative XRD peak intensities while the hydride phase expected from the Mg—Ni alloy—Mg₂NiH₄—was not detected. We conclude that in our composite the Mg—Ni alloy participates in hydrogen sorption catalytically, but does not contribute meaningfully to active hydrogen storage. To explore the reversibility and stability of this performance, a cycle test was performed at 125° C./300° C. for 30 cycles (FIG. 2d). The absorption/desorption cycle experiments were carried out consecutively in a closed system without evacuation between cycles, which mimics real-world fueling conditions. Furthermore, it was achieved under a relatively mild condition of 15 bar of initial pressure for absorption—compared to a compressed hydrogen gas tank which requires 350 bar at minimum. The capacity and kinetics of hydrogen absorption/desorption were maintained during the cycles, although a small amount of residual MgH₂ (less than 0.1 wt. %) from repeated absorption/desorption remained upon the completion of all 30 cycles.

Thermodynamics of Ni-Doped rGO-Mg for Hydrogen Absorption/Desorption.

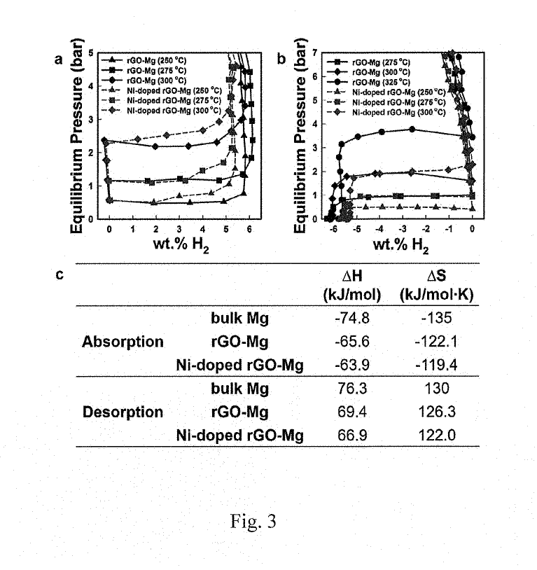

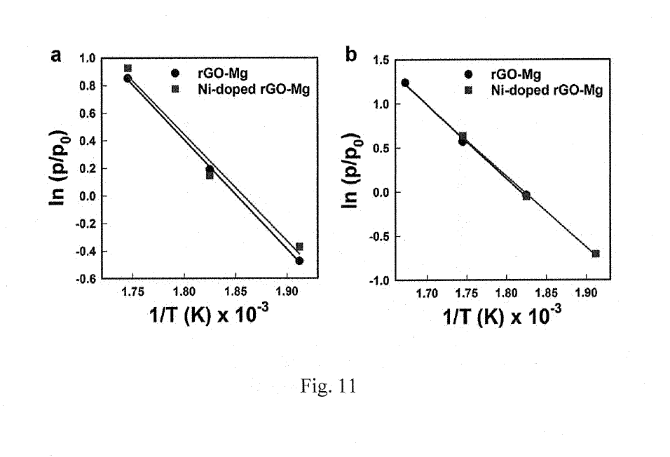

To quantitatively understand the thermodynamic properties of the dual-doped composites, pressure-composition-temperature (PCT) measurements were performed at three different temperatures for each absorption/desorption (FIG. 3a). To investigate the effects of transition-metal doping, PCT curves for the undoped rGO-Mg composite were also obtained. Each PCT plot for the Ni-doped rGO-Mg composite exhibits a single equilibrium plateau region, indicating that only one hydriding mechanism—Mg to MgH₂—exists, while Mg—Ni composites with a higher concentration of Ni (e.g. above 10%) have two plateau regions resulting from dual hydriding processes with Mg to MgH₂ and Mg₂Ni to Mg₂NiH₄.³⁷ The formation of a single hydride phase corroborates the aforementioned XRD analysis where no Mg₂NiH₄ peak was observed after hydriding-even with the presumptive existence, the amount of Mg₂NiH₄ would be extremely low to be detected on either XRD or PCT measurement, which is plausible considering that the Mg—Ni alloy peak on XRD is fairly weak. To elucidate the thermodynamic values of these composite materials, both enthalpy and entropy changes upon hydrogen absorption and desorption were determined by fitting the PCT curves to van't Hoff plots (see FIG. 11), and the results are shown in FIG. 3c. Both hydrogen absorption and desorption enthalpies are reduced for the nanostructured rGO-Mg composites as compared to bulk Mg. Overall, the enthalpy change for the Ni-doped rGO-Mg composites is reduced by approximately 11 kJ/mol and 9 kJ/mol, respectively, for hydriding and dehydriding processes. The further enthalpy decrease with Ni doping was relatively small when compared to the undoped composite; hence, the thermodynamic enhancement is mainly attributed to the nanosizing and rGO encapsulation in the composite. Remarkably, the thermodynamic enhancements measured for both undoped and doped rGO-Mg composites are computed based on the entire system mass, including the rGO matrix, which is dead mass for hydrogen sorption. Considering that this is an enhancement for the total active composite, it is a substantial advance beyond reports in the literature where catalysis (even in composites) is misleadingly reported only on a per-atom or per-active material basis. The approach we use better enables comparison of the efficacy of doping across material classes.

Structural Analysis of Ni-Doped rGO-Mg Composites.

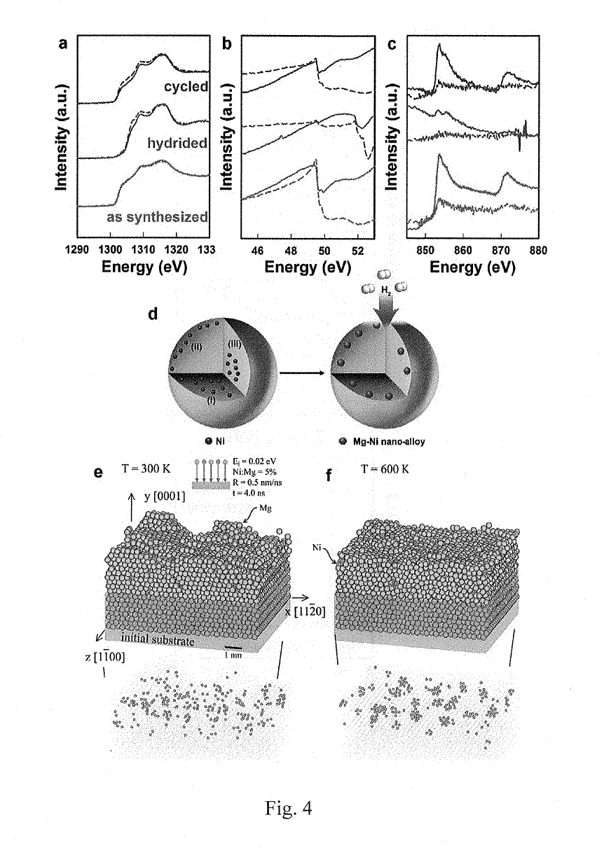

To closely scrutinize the interaction between rGO layers and the Ni-doped Mg crystals, as well as the oxidation state of Mg and Ni metals in the composite along with the incorporation and distribution of Ni within Mg crystals, X-ray absorption near-edge structure (XANES) measurements were performed. Both Mg K- and L-edge spectra confirm the presence of zero-valent Mg metal—a characteristic K-edge peak shoulder located at 1303 eV and a unique sharp L-edge peak protruding at 49.8 eV (FIGS. 4a, b). These features are observed in both TEY (total electron yield) and TFY (total fluorescence yield) modes, which report information on the surface and the bulk material characteristics, respectively. This demonstrates that the zero-valent state of Mg crystals is well preserved over the composites. An upshift of these characteristic peaks was detected with the hydrided Ni-doped rGO-Mg composites for both K- and L-edge, indicating that the chemical state is switched from the zero valent metal to the positive state as a result of hydriding. The peaks were downshifted again for the cycled samples, signaling the recovery of the Mg metallic state. In addition, two distinctive peaks at 853 eV and 871 eV were identified as Ni the Ni L-edge measurements for as-synthesized and cycled Ni-doped rGO-Mg composites (FIG. 4c). We also observed a weak splitting of the peak at 853 eV for the hydride samples, suggesting possible interaction with hydrogen; however, the absence of any Mg₂NiH₄ signature in XRD indicates that direct Ni—H binding contributes negligibly to the overall hydrogen uptake. Interestingly, these Ni peaks are only present in TEY mode, which is surface sensitive, but they are negligibly weak in TFY, which probes bulk properties. The discrepancy between TEY and TFY scans illustrates that Ni atoms are spatially inhomogeneous in Mg crystals, with most of them localized near the surface. Thus, the Mg—Ni nano-alloy is likely located near the surface (FIG. 4d), effectively catalyzing the hydriding/dehydriding processes of the composites. These measurements give insight into the possible mechanisms by which Mg—Ni nano-alloys participate in hydrogen absorption in these materials, which will be discussed in detail in the sections below.

To provide additional insights into the nature of the Mg—Ni nano-alloys and their elevated-temperature evolution, molecular dynamics (MD) vapor deposition simulation methods were used to computationally synthesize Mg-5% Ni crystals at low (300K) and high (600K) temperatures (FIGS. 4e, f). As shown in FIG. 4e, at the low temperature condition Ni atoms tend to be randomly distributed in the Mg lattice to form a solid solution. In contrast, at the high temperature condition they aggregate to form clusters containing both Mg and Ni (FIG. 4f). Hence, we can conclude that the formation of Mg—Ni nano-alloys becomes both thermodynamically favored and kinetically achievable at elevated temperatures. Although more detailed structural analysis and longer simulations would be required to determine whether these individual clusters might eventually form stoichiometric Mg₂Ni, this simulation result generally confirms the irreversible Mg—Ni nano-alloy formation at high temperatures that was proposed based on the experimental observations.

In-Situ X-Ray Absorption Near-Edge Structure (XANES) Upon Hydriding.

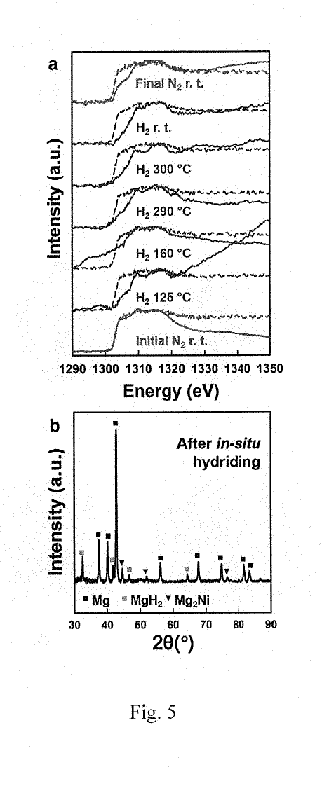

To elucidate structural changes during hydriding, in-situ XANES measurements were performed under low (1 bar) H₂ pressure (FIG. 5a). The Ni-doped rGO-Mg powder was exposed to air prior to being loaded into a measuring cell. An initial scan under nitrogen atmosphere at room temperature confirmed that the Mg metal state was well preserved in both TEY and TFY, consistent with the ex-situ result (FIG. 4a). In the subsequent scans upon temperature ramping under 1 bar of H₂, however, an abrupt peak shift was observed at 125° C., implying immediate transformation from Mg to MgH₂, which was retained during further temperature elevation and cooling down to room temperature. Notably, this shift is observed only in surface-sensitive TEY, while TFY shows that a zero-valent Mg metal state is maintained in bulk. Considering that the hydrogen pressure was merely 1 bar, it is reasonable to propose that hydriding took place only near the surface. A separate PCT measurement also showed that approximately 1 wt. % of hydrogen was absorbed under similar conditions, in contrast to 6.5 wt. % of hydriding achieved at higher pressures. In a XRD pattern obtained in succession to in-situ XANES, both Mg and MgH₂ phases were observed along with the Mg₂Ni alloy, consistent with a partial surface hydriding (FIG. 5b). Upon back-flowing N₂ gas in the final XANES scan, a slight downshift was observed on the shoulder. However, because the subsequent XRD measurement confirmed the retention of MgH₂, we speculate that this shift is instead related to the elimination of a transitory Mg₂NiH₄ hydride on the surface that vanishes for hydrogen-depleted conditions because the Mg₂NiH₄ phase is thermodynamically less stable. Most importantly, this data conclusively demonstrates the stable formation of MgH₂ near the surface of Mg nanocrystals under remarkably mild conditions of only 1 bar of H₂—an unprecedented result confirmed by in-situ X-ray measurements which was only feasible because of the superior hydriding kinetics and environmental robustness of Ni-doped rGO-Mg.

Kinetic Analysis for Hydrogen Absorption and Desorption.

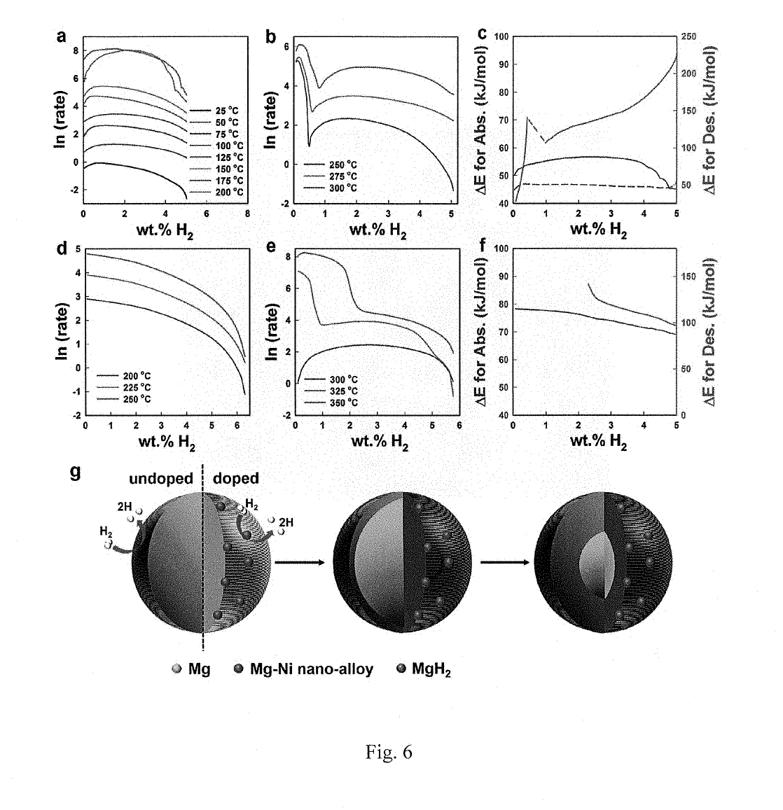

While the enhanced thermodynamics by rGO-encapsulation was confirmed by PCT measurements, the kinetic enhancements associated with the Ni-doped Mg composite materials were quantified by calculating activation energies (ΔE) for absorption/desorption. This was done by fitting the measured rate of hydrogen absorption/desorption to an Arrhenius law at each composition. Interestingly, this results in reaction rates and barriers that change as the reaction progresses, rather than a single barrier for the entire process (FIGS. 6c, f), thus reflecting important changes in the reaction kinetics as absorption/desorption proceeds. The absorption/desorption rates and ΔE for Ni-doped rGO-Mg (FIGS. 6a-c) are juxtaposed with undoped rGO-Mg (FIGS. 6d-f) to highlight the specific catalytic effects of Ni-doping. For unbiased evaluation of the hydrogen sorption kinetics, our kinetic analysis was conducted using the total composite values for wt. % H₂, not solely based on Mg content. While this is in contrast to some literature reports, this method of reporting data more realistically reflects actual performance.

To gain mechanistic insight into FIG. 6, we comprehensively assess dominant mechanisms and rate-limiting processes that may be active during different reaction stages of hydriding/dehydriding and compared literature-reported barriers for these processes against our extracted barriers (see Table 1). In general, the formation of metal hydrides involves a chain of possibly rate-limiting reactions: H₂ surface adsorption and dissociation, H chemisorption, H migration from the surface to the interior, H solid-state diffusion, and nucleation and growth of the hydride phase. After eliminating certain processes which are already kinetically facile in the undoped case, we conclude that hydriding in Ni-doped rGO-Mg likely becomes limited by diffusion through the outer layers of the hydride because the Mg—Ni nano-alloy phase catalyzes the otherwise slow dissociation of H₂. On the other hand, dehydriding involves a fast initial discharge of hydrogen near surface, followed by a slower nucleation/growth behavior which is less affected by the presence of Ni dopants.

To reach these conclusions, we first analyzed the absorption kinetics of undoped rGO-Mg, for which the energy barrier is initially high and decreases as absorption proceeds (blue line in FIG. 6f). According to Table 1, for hulk Mg the hydriding rate limitations arise from H₂ dissociation on Mg (ΔE=87-116 kJ/mol) and subsequent hydrogen diffusion through an MgH₂-rich outer region that grows as the reaction proceeds (>100 kJ/mol through pure MgH₂). On the other hand, for nano-sized Mg, a crystalline MgH₂ shell does not form completely due to surface stresses associated with volume mismatch; consequently, faster pathways through near-surface boundary regions, featuring non-stoichiometric compositions or structural disorder, become feasible. This effect explains barriers lower than 100 kJ/mol observed in the undoped rGO-Mg (FIG. 6f) with respect to bulk Mg, as well as the gradual barrier decrease with hydrogen content as the evolving microstructure causes the boundary regions begin to contribute more prominently.

Unlike undoped rGO-Mg, the barrier of ˜45-55 kJ/mol for Ni-doped rGO-Mg remains relatively consistent throughout the absorption reaction (blue lines in FIG. 6c). According to Table 1, Ni doping reportedly lowers the barrier for H₂ dissociation from ˜87-116 on bulk Mg to ˜6-19 kJ/mol, indicating that this process is no longer practically considered rate-limiting. Instead, atomic hydrogen diffusion away from the catalytic Ni site and through the outer shell region become the likely candidate rate-limiting steps which agree with our kinetic data; the former has a reported barrier of 26-50 kJ/mol and the latter depends on the fraction and nature of “fast” boundary pathways in the near-surface region that exhibit behavior similar to the later absorption stages of undoped rGO-Mg. The weak dependence of the barrier on hydrogen concentration provides an additional clue, since the catalyzed process should not depend on the evolution of the microstructure. To understand this, consider that Ni dopants can introduce additional fast pathways due to formation of interfaces with the Mg—Ni nano-alloy near the surface, which can be associated with additional mechanical stresses, non-stoichiometric compositions, and structural disorder (hints of this can be seen in the MD simulations in FIG. 4e-f). Although the relevant diffusion barrier in Ni-doped rGO-Mg is difficult to predict, it was reported that similar interfaces in bulk Mg/Mg₂Ni eutectoids decrease the barrier up to ˜58 kJ/mol, in reasonable agreement with our observed kinetics in FIG. 6c. Simultaneously, the presence of Ni suppresses MgH₂ surface layer growth, which makes slow diffusion through MgH₂ (ΔE>100 kJ/mol) less relevant during hydrogen insertion. Notably, because these mechanisms are related with the introduction of Ni-containing clusters rather than the evolution of the hydride surface phase, the corresponding barriers should not depend significantly on the degree of hydriding, as we observe. Additional interesting behavior occurs at temperatures beyond 175° C., where the rate performance is somewhat inconsistent with the lower temperatures (notice the different fits obtained by including or excluding these data in FIG. 6c). We speculate that at these temperatures, thermal disordering in the surface region contributes supplemental structural and chemical inhomogeneity that enhances the fraction of fast diffusive pathways.

Compared to hydriding, dehydriding is less enhanced by the addition of Ni; accordingly, for brevity we do not discuss details of the process here. However, hypothesized dehydriding mechanisms based on the calculated rates and ΔE in FIGS. 6b-c and 6e-f are summarized in the Supplementary Information (including Table 1), and highlight the additional favorable role of internal particle stresses exerted on the particle by the Mg—Ni nano-alloys.

Significantly, our proposed mechanisms suggest that the enhanced absorption and desorption kinetics result from at least two synergistic chemomechanical factors: nanoconfinement favors incomplete MgH₂ formation to introduce additional near-surface diffusion pathways, whereas Ni-doping changes the nature and concentration of these pathways, catalyzes H₂ dissociation, and exerts favorable stresses on the particle core. Accordingly, “inside-out” doping (i.e., Ni-dopants and rGO encapsulation) appears to have enabled an entirely new path toward optimizing Mg as a hydrogen storage material.

We have demonstrated robust, environmentally stable Mg nanocrystals with Ni as a dopant for a high-performance hydrogen storage material. Among a series of 3d-transition metal dopants, Ni stands out as a high performing additive whose functionality is connected to the formation of a Mg—Ni nano-alloy phase. The thermodynamic and kinetic barriers to hydrogen absorption/desorption are significantly improved with a synergistic effect of nanosizing, rGO encapsulation and Ni doping, notably without sacrificing the high hydrogen sorption capacity of the composite (6.5 wt % of H₂ at the system level). The Ni dopants are found to localize primarily near the surface, likely promoting the dissociation of H₂ molecules and facilitating subsequent migration of H atoms. As reported previously, the use of encapsulating rGO layers can selectively sieve H₂ molecules on the surface, preventing the penetration of other gas molecules such as O₂. Leveraging these complementary functionalities, the Ni-doped rGO-Mg composites achieve remarkably high performance in both capacity and transport kinetics with excellent air stability. Potentially, other 3d-transition metals could similarly act as high performing catalysts in a stable and reproducible way, pending formation of nano-alloy phases under controlled conditions. The composite material presented in this work elucidates the mechanism by which this “inside-out” doping system participates in both thermodynamics and kinetics of hydrogen storage materials and provides a new platform for practical use of hydrogen storage for mobile applications.

### Methods

Materials.

Bis(cyclopentadienyl) magnesium 99.99+% (Cp₂Mg), Bis(cyclopentadienyl)titanium dichloride, 99+% (Titanocene dichloride) (Cp₂TiCl₂), Bis(cyclopentadienyl)chromium, min. 95%, sublimed (Chromocene) (Cp₂Cr), Bis(cyclopentadienyl)manganese, 98+% (Manganocene) (Cp₂Mn), Bis(cyclopentadienyl)cobalt(II), min. 98% (Cobaltocene) (Cp₂Co), Bis(cyclopentadienyl)iron, 99% (Ferrocene) (Cp₂Fe), Bis(cyclopentadienyl)nickel, 99% (Nickelocene) (Cp₂Ni) were purchased from Strem Chemicals. Single layer graphene oxide was purchased from ACS Material, LLC. Lithium foil 99% was purchased from Alfa Aesar. Naphthalene 99% was purchased from Sigma Aldrich. Tetrahydrofuran (THF) was distilled before use.

Synthesis of 3d-Transition Metal Doped rGO-Mg.

A series of 3d-transition metal doped rGO-Mg composites were prepared in an argon glove box. Each composite was synthesized following the same procedure, varying only the transition metal incorporated. Lithium naphthalenide solutions were prepared by dissolving naphthalene (18.5 mmol, 2.52 g) in THF (120 mL), followed by the addition of Li metal (27.2 mmol, 0.189 g). GO (6.56 mg) was dispersed in THF (13.1 mL), sealed in a glove box and sonicated for 1.5 hours. Cp₂Mg (15 mmol, 2.31 g) and each transition metal precursor (0.75 mmol, 0.028 g for Cp₂Ni) were dissolved in THF (22.5 mL) and the solution was added into the GO solution and then stirred for 30 minutes. The combined solution was mixed with the lithium naphthalenide solution, then stirred for another 2 hours. The resultant solution was centrifuged for 20 minutes at 10,000 rpm and washed with THF twice (10,000 rpm, 20 minutes). The final product was completely dried under vacuum overnight.

Characterization and Instrumentation.

High resolution TEM images were obtained with JEOL 2100-F Field-Emission Analytical Transmission Electron operated at 200 kV and with Philips CM300FEG/UT at 300 kV. XRD patterns were obtained with a Bruker AXS D8 Discover GADDS X-Ray Diffractometer, using Co Kα radiation (λ=0.179 nm). Hydrogen absorption/desorption kinetic measurements were conducted using a HyEnergy Sieverts PCT Pro-2000 at 15 bar/0 bar of hydrogen at different temperatures. The PCT measurement was performed on the sample after running one absorption/desorption cycle. XANES measurements were performed on Beamline 8.0.1.3, 6.3.1.2, and 4.0.3 at the Advanced Light Source (ALS), Lawrence Berkeley National Laboratory. The energy resolution was set to 0.1 eV and the experimental chamber had a base pressure of 1×10⁻⁸ torr. A reference sample was measured before and after all XANES measurements for energy calibration. The XANES spectra were recorded using total electron yield and total fluorescence yield detection modes. For in-situ XANES measurement, the cell was purged with nitrogen gas 12 hours prior to characterization. The temperature increased afterwards, simultaneously replacing nitrogen with hydrogen gas in the cell at a pressure of 1 bar; the TEY and TFY scans were performed successively until the temperature was equilibrated at 300° C. The hydrogen pressure was deliberately set to 1 bar-comparatively very low for conventional metal hydride studies, for the purpose of monitoring gradual phase conversion upon temperature ramping.

Md Simulation.

A previously developed and tested embedded atom method (EAM) interatomic potential was used in this MD model. The initial substrates were pure Mg in the [0001] orientation. The crystal growth was conducted at an adatom energy of 0.02 eV, a vapor flux ratio of Ni:Mg=5%, and a growth rate of 0.5 nm/ns. The atomic structures obtained after 4.0 ns of deposition are shown in FIGS. 4e and 4f for 300 K and 600 K temperatures respectively (the original substrate is indicated in FIG. 4e-f).

Kinetic Energy Barrier Calculations.

Kinetic parameters characterizing the absorption and desorption processes (such as rate constants and energy barriers) are often obtained by fitting experimental data to simple kinetic models, such as e.g. the Johnson-Mehl-Avrami model. However, we have found that such models can fail to accurately fit the absorption/desorption data over the entire range of the reaction, making it difficult to extract reliable kinetic parameters from such an approach. For this reason, we instead obtain energy barriers by fitting the measured reaction rates (defined as the rate of change of absorbed weight of hydrogen) to an Arrhenius law at each stage of the reaction; i.e. we fit to an Arrhenius law for the rate r of the form r=f(x)*exp(−E(x)/kT), where the prefactor f(x) and energy barrier E(x) are assumed to be functions of the absorbed weight of hydrogen x. This approach allows one to extract effective energy barriers that are not biased by the underlying assumptions of any particular kinetic model, and moreover can provide evidence of changes in the reaction mechanism as absorption or desorption proceeds.

Rates were calculated by fitting the experimental data (shown in FIGS. 2a and b) using the LOWESS method, and extracting the rates from the slope of the fits as a function of absorbed weight of hydrogen, see FIG. 6. Using a flexible non-parametric fitting method such as LOWESS allows all features of the experimental data to be captured (in particular the abrupt change in desorption rate after the early stages of desorption), which is not possible by fitting to simple functional forms from kinetic models. Energy barriers were then calculated from a linear fit of log(r) vs 1/T at each value of absorbed weight x.

Proposed Desorption Mechanisms for Undoped and Ni-Doped rGO-Mg

In this section we discuss the possible kinetic limitations during H₂ desorption for undoped and Ni-doped rGO-Mg based on the rates in FIGS. 6b-c, 6e-f, and Table 1.

For both undoped and Ni-doped rGO-Mg, multiple distinct dehydriding mechanisms can be identified from the kinetic analysis in FIG. 6. For early reaction stages, a faster desorption process (<50 kJ/mol from the red line in FIG. 6c) dominates, implying that hydrogen is easier to access; this points towards a surface or near-surface process. Therefore, it logically follows that at this initial stage, there is a limited amount of hydrogen that becomes easier to extract near the surface in the presence of Ni dopants. This initial surface process is only dominant up to a certain hydrogen loading; for example, the end of this surface process is characterized by the dips in the rate curves in FIG. 6b. We speculate that such a surface process is connected to the presence of the same disordered regions that were discussed for hydriding processes in the main text. These regions are associated with Mg—Ni nano-alloy interfaces in the Ni-doped case and thermally disordered regions in the undoped case, and tend to generate faster diffusion pathways. The different origins in the doped and undoped cases are reflected in the corresponding temperature sensitivities of the extent of the initial dehydriding regime: for Ni-doped rGO-Mg, the associated composition range is only weakly dependent on temperature (FIG. 6b), whereas the dependence for the undoped case is quite strong (FIG. 6e).

Following desorption from the near-surface region, there are a wide range of compositions that follow a characteristic nucleation-growth profile, with a barrier of 100 kJ/mol or higher for both the doped and undoped cases. It is reasonable to assume that this range is associated with the formation of crystalline Mg. The growth limitation in this range is likely related to the desorption of H₂ from Mg (˜87-116 kJ/mol)^{9, 12-16}, in agreement with our kinetics data in FIGS. 6c and f), which is a required step for both doped and undoped rGO-Mg that is only weakly catalyzed by the introduction of Ni. The similarity of the barriers for doped and undoped cases explains why desorption is not significantly enhanced by Ni doping through this particular section of the reaction.

A final benefit of Ni dopant is evident at higher temperatures in the final stages of dehydriding. Compared with the undoped sample, Ni-doped rGO-Mg exhibits a higher hydrogen release-to-uptake ratio (i.e., reversible hydrogen extraction) as the temperature increases. This is reflected in the increased effective energy barrier as dehydriding proceeds in the Ni-doped sample (FIG. 6c), which indicates that the small amount of hydrogen that otherwise tends to remain in the undoped sample can be thermally released (with a higher barrier) as long as Ni is present and the temperature is sufficiently high. The mechanism for this enhancement is not immediately clear; however, we postulate that it is connected to the additional mechanical stress exerted on the particle core by the Mg—Ni nano-alloy. This stress will tend to destabilize the remaining hydrogen-containing clusters, facilitating hydrogen release.

### SUMMARY

The invention consists of a composite of magnesium nanoparticles containing a metal catalyst all within a gas-selective polymer, which renders the nanomaterial air stable. Magnesium is one of the most promising inorganic materials for hydrogen storage. Magnesium hydride (MgH₂) has a high hydrogen capacity of 7.6 weight %. The theoretical volumetric capacity of these composites is 55 g/L. This value is 180% greater than traditional compressed hydrogen gas cylinders (10,000 psi, 30 g/L). However, serious obstacles remain to the implementation of magnesium hydride for practical use. High bond formation enthalpy, slow hydrogen uptake and release kinetics, and high release temperatures renders magnesium hydride impractical for hydrogen storage. The Department of Energy has set ultimate temperature targets of 20 oc for absorption and 90 oc for desorption of hydrogen. In the present invention, we develop the synthetic methodology for metallic magnesium nanocomposites containing metal catalyst. Nanoscale metallic magnesium has a high surface area, short diffusion lengths for hydrogen, and reduced enthalpic barriers toward hydrogen molecules. By incorporating select metal catalyst dopants (for example titanium, palladium, etc.), hydriding may be catalyzed by the decrease in activation energy of H2 gas dissociation into hydrogen atoms on the metal surface. Additionally, other metal catalyst dopants (for example nickel, cobalt, copper, iron, etc.) may increase the kinetics of dehydrogenation due to an increase in the number of grain boundaries at the interface between metal hydride and the dopant metal, or strain induced within the metal hydride. We have currently doped our magnesium-polymer composites with titanium and nickel, achieving fast hydrogen absorption at room temperature. This is a dramatic improvement over other magnesium based systems which require temperatures in excess of 200 C. In addition, through inclusion of metal dopants we have reduced the time required for hydrogen desorption at 300 C.

TABLE 1
Summary of reported barriers for possible mechanisms
and rate-limiting processes governing hydrogen absorption/desorption
in undoped and Ni-doped Mg.

| | | Energy barrier |
|---|---|---|
| | Mechanism | (kJ/mol) |
| Bulk | H diffusion by H interstitial | 17.4-38.6 (expt) |
| diffusion | in Mg | 19.3-38.6 (calc) |
| | H diffusion by H vacancy in | 95.5 (expt) |
| | MgH₂ | 36.7-212.3 (calc) |
| | H diffusion in H-charged | 57.9 |
| | Mg + Mg₂Ni eutectoid | |
| Surface | Surface diffusion of H* in Mg | 0-28.9 |
| diffusion | Surface diffusion of H* in | 26.1-48.2 |
| | Ni-doped Mg | |
| | Surface to bulk diffusion of | 29.9-72.4 |
| | H* in Mg | |
| H₂ absorption | Dissociation/absorption of | 86.8-115.8 |
| | H₂ on Mg surface | |
| | Dissociation/absorption of | 5.8-19.3 |
| | H₂ on Ni-doped Mg surface | |
| | Dissociation/absorption of | 28.9 |
| | H₂ on MgH₂ surface | |
| H₂ desorption | Association/desorption of | 86.8-106.1 |
| | H₂ on Mg surface | |
| | Association/desorption of | 67.5-77.2 |
| | H₂ on Ni-doped surface | |
| | Association/desorption of | 170.8-176.6 |
| | H₂ on MgH₂ surface | |

1. A composition of matter comprising:
a transition metal doped magnesium (Mg) nanocrystal encapsulated with reduced graphene oxide (rGO).

2. The composition of matter of claim 1, wherein the rGO forms layers on an outer surface of the transition metal doped Mg nanocrystal.

3. The composition of matter of claim 1, wherein the transition metal comprises at least one of titanium (Ti), chromium (Cr), magnesium (Mn), iron (Fe), cobalt (Co), and nickel (Ni).

4. The composition of matter of claim 1, wherein the transition metal comprises nickel (Ni).

5. The composition of matter of claim 4, wherein the transition metal doped Mg nanocrystal comprises a Mg—Ni nano-alloy, and wherein the Mg—Ni nano-alloy comprises Mg₂Ni nanocrystallites.

6. The composition of matter of claim 1, wherein the transition metal doped Mg nanocrystal is approximately 3 nanometers to 4 nanometers in diameter.

7. The composition of matter of claim 1, wherein upon hydrogen absorption, a Mg phase is converted to MgH₂.

8. The composition of matter of claim 1, wherein upon hydrogen absorption, a Mg₂Ni phase is converted to Mg₂NiH₄.

9. A method of making transition metal doped reduced graphene oxide (rGO)-magnesium (Mg) nanocrystals comprising:
preparing a first solution by dissolving naphthalene in tetrahydrofuran (THF) followed by the addition of Li metal to form lithium naphthalenide;
preparing a second solution by dispersing graphene oxide (GO) in THF;
preparing a third solution by dissolving Bis(cyclopentadienyl) magnesium (Cp₂Mg) and a transition metal precursor in THF;
forming a combined solution by adding the third solution to the second solution;
forming a resultant solution by mixing the combined solution with the first solution; and
centrifuging the resultant solution.

10. The method of claim 9, wherein the transition metal comprises at least one of titanium (Ti), chromium (Cr), magnesium (Mn), iron (Fe), cobalt (Co), and nickel (Ni).
